(19) United States
(12) Patent Application Publication
(10) Pub. No.: US 2005/0280447 A1
(43) Pub. Date: Dec. 22, 2005

(54) Low voltage selection control circuit for dual power supply systems

(76) Inventors: Susan A. Curtis, Sherman, TX (US); Christopher M. Cooper, Denison, TX (US)

Correspondence Address: TEXAS INSTRUMENTS INCORPORATED, P O BOX 655474, M/S 3999, DALLAS, TX, 75265, US

(21) Appl. No.: 10/869,529

(22) Filed: Jun. 16, 2004

(51) Int. Cl. H03K 5/153

(52) U.S. Cl. 327/74

(57) ABSTRACT

The power supply selection control circuit includes: a first comparator; a second comparator; a first reference generator coupled to a first power supply node, and having a first reference output node coupled to a first input of the first comparator and to a first input of the second comparator; and a second reference generator coupled to a second power supply node, and having a second reference output node coupled to a second input of the first comparator and to a second input of the second comparator. The first comparator provides a logic low when the first power supply voltage is lower than the second power supply voltage. The second comparator provides a logic low when the second power supply voltage is lower than the first power supply voltage.

### FIELD OF THE INVENTION

The present invention relates to electronic circuitry and, in particular, to voltage selection circuits.

### BACKGROUND OF THE INVENTION

Consider two systems, one operating at 3.3 v and one operating at 1.5 v. If a 3.3 v supply is applied to the control circuitry, the control inputs will have a threshold of about 1.65 v, or approximately ½ of the supply voltage. Signals generated by the 1.5 v system will not be high enough to switch this input. Only input signals generated by the 3.3 v system will be able to drive the control inputs. If the 1.5 v supply powers the control inputs, the input threshold will be about 0.75 v and would recognize either 1.5 v or 3.3 volts as a valid high input voltage. Traditional methods of handling two separate supplies frequently involve using diodes in such a way that an internal reference to the highest supply is generated. A reference to the lowest supply is what is needed in this situation.

FIG. 1 shows a prior art circuit used to reference the input control circuit to either of two power supplies VCCA and VCCB. The prior art circuit of FIG. 1 includes diodes D1 and D2; transistors P1 and P2; inverter INV1 (input control circuit); input signals ALOW and BLOW; Control input node and Control out node; and internal supply node int_power. Successful implementation of the circuit of FIG. 1 requires providing the input signals ALOW and BLOW, such that ALOW is a logic low when VCCA<VCCB, and BLOW is a logic low when VCCB<VCCA, without restricting the supply voltage range. Previous attempts to use this circuitry have not been entirely successful. They required that the two supplies differ by at least one threshold voltage (Vt) (approximately 0.7 v) or both supplies could be disabled.

### SUMMARY OF THE INVENTION

The power supply selection control circuit includes: a first comparator; a second comparator; a first reference generator coupled to a first power supply node, and having a first reference output node coupled to a first input of the first comparator and to a first input of the second comparator; and a second reference generator coupled to a second power supply node, and having a second reference output node coupled to a second input of the first comparator and to a second input of the second comparator. The first comparator provides a logic low when the first power supply voltage is lower than the second power supply voltage. The second comparator provides a logic low when the second power supply voltage is lower than the first power supply voltage.

### BRIEF DESCRIPTION OF THE DRAWINGS

In the drawings:

FIG. 1 is a circuit diagram of a prior art voltage selection circuit;

FIG. 2 is a circuit diagram of a preferred embodiment control circuit for providing the input signals to the prior art voltage selection circuit of FIG. 1.

### DETAILED DESCRIPTION OF PREFERRED EMBODIMENTS

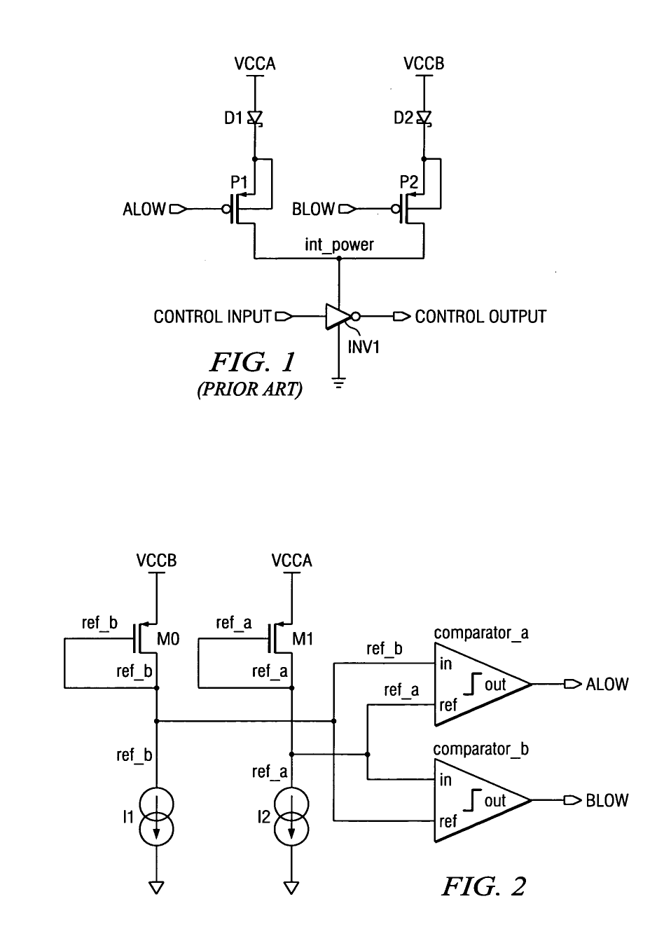

The present invention is a circuit that provides the input signals needed for ALOW and BLOW, shown in FIG. 1, based on the lower of the two supplies. The circuit operates correctly over the entire voltage range for supplies VCCA and VCCB. This results in a dynamic logic threshold that is based on the lower of the two supplies, increasing system flexibility.

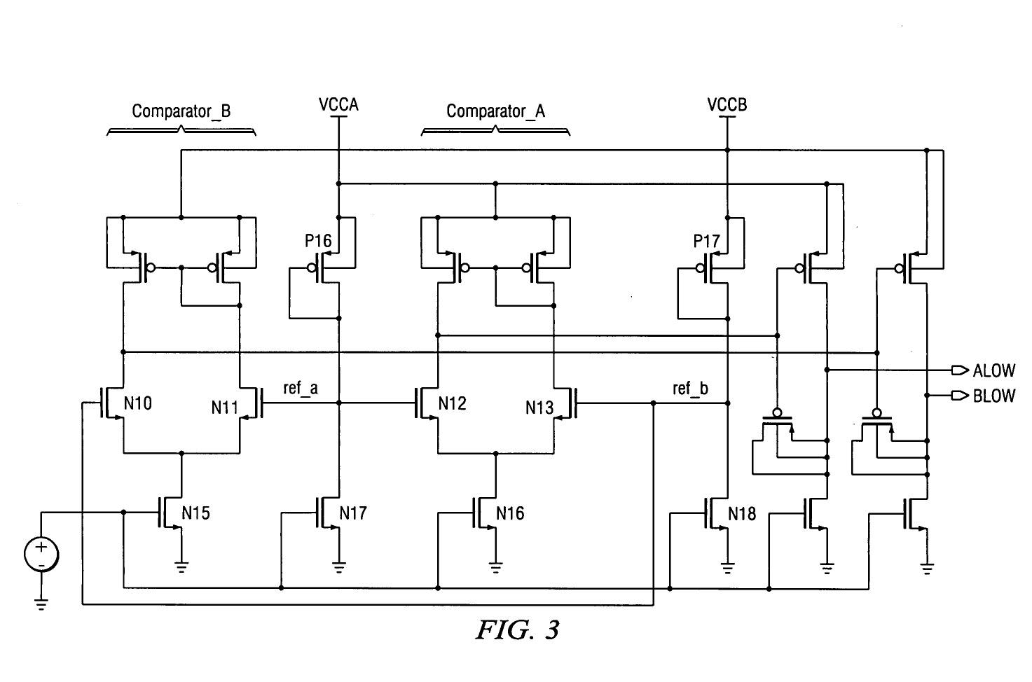

The preferred embodiment circuit, shown in FIG. 2, summarizes the operation of this solution. The circuit of FIG. 2 includes transistors M0 and M1; current sources I1 and I2; comparators comparator_a and comparator_b; power supplies VCCA and VCCB; and outputs ALOW and BLOW. Two reference signals ref_a and ref_b are generated from the system power supplies which are then compared against each other to produce logic level signals ALOW and BLOW. These signals are produced such that ALOW will be at a low logic level when the corresponding power supply VCCA is at a lower voltage than supply VCCB. Similarly, BLOW is at a low logic level when VCCB is at a lower voltage than VCCA. These logic signals ALOW and BLOW are the inputs needed for the circuit of FIG. 1.

The circuit of FIG. 3 is an example implementation of the device of FIG. 2. The outputs from the circuitry of FIG. 3, ALOW and BLOW, are the input signals for the control circuitry shown in FIG. 1. Comparators comparator_a and comparator_b in FIG. 3 consist of two analog differential amplifiers formed by differential pairs N10/N11 and N12/N13 along with their current sources N15/N16. Comparator_a is powered from supply VCCA and comparator_b is powered by supply VCCB allowing output signals ALOW and BLOW to have the correct logic high and low signal levels for the associated system. The voltage of signal ref_a is level shifted from supply VCCA and the voltage signal ref_b is level shifted from supply VCCB by using a current sources N17/N18 working against active loads P16/P17. Signals ref_a and ref_b become the input to the differential amplifiers at the gates of transistors N10, N11, N12 and N13. If supply VCCA is the lower voltage of the two supplies, ALOW will be a logic low level. Similarly, if supply VCCB is the lower voltage of the two supplies, BLOW will be a logic low level. If ALOW is a logic low, the circuitry of FIG. 1 is powered by supply VCCA and if BLOW is a logic low, the circuitry in FIG. 1 is powered by supply VCCB. Diodes D1 and D2, shown in FIG. 1, prevent current flow between supply VCCA and VCCB if ALOW and BLOW are both low. Sizing transistors N10 and N12 slightly smaller than transistors N11 and N13 ensures ALOW and BLOW will never both be logic high in the region where supply VCCA is approximately equal to supply VCCB. When VCCA<VCCB, ALOW is low. When VCCA>VCCB, BLOW is low. When supplies VCCA and VCCB are approximately equal, both ALOW and BLOW are at a low logic level.

No restriction is required on the power supply ranges. Power supplies provide both power and differential inputs.

Most prior art techniques involve using diodes to find the highest power supply level. This is done through a diode connection in such a way that the high supply powers the circuit but does not tell which supply is providing that level. This forces logic levels to be referenced to the highest supply. The preferred embodiment circuit produces an output signal indicating which supply is the lower voltage, and provides a dynamic threshold that is based on the lower of the two supplies, resulting in increased system flexibility.

One prior art attempt involved a circuit that would generate an output signal that indicated which supply was lowest, however it required that the two supplies differ by at least one Vt (approximately 0.7 v). The preferred embodiment solution does not require restricting the power supply range.

While this invention has been described with reference to an illustrative embodiment, this description is not intended to be construed in a limiting sense. Various modifications and combinations of the illustrative embodiment, as well as other embodiments of the invention, will be apparent to persons skilled in the art upon reference to the description. It is therefore intended that the appended claims encompass any such modifications or embodiments.

1. A power supply selection control circuit comprising:
a first comparator;
a second comparator;
a first reference generator coupled to a first power supply node, and having a first reference output node coupled to a first input of the first comparator and to a first input of the second comparator; and
a second reference generator coupled to a second power supply node, and having a second reference output node coupled to a second input of the first comparator and to a second input of the second comparator.

2. The circuit of claim 1 wherein an output of the first comparator is a logic low when a voltage on the first power supply node is less than a voltage on the second power supply node.

3. The circuit of claim 1 wherein an output of the second comparator is a logic low when a voltage on the second power supply node is less than a voltage on the first power supply node.

4. The circuit of claim 1 wherein the first reference generator provides a level shifted version of a voltage on the first power supply node.

5. The circuit of claim 1 wherein the second reference generator provides a level shifted version of a voltage on the second power supply node.

6. The circuit of claim 1 wherein the first reference generator comprises:
a diode-connected transistor coupled between the first power supply node and the first reference output node; and
a current source coupled between the first reference output node and a common node.

7. The circuit of claim 1 wherein the second reference generator comprises:
a diode-connected transistor coupled between the second power supply node and the second reference output node; and
a current source coupled between the second reference output node and a common node.

8. A power supply selection circuit comprising:
a first comparator;
a second comparator;
a first reference generator coupled to a first power supply node, and having a first reference output node coupled to a first input of the first comparator and to a first input of the second comparator;
a second reference generator coupled to a second power supply node, and having a second reference output node coupled to a second input of the first comparator and to a second input of the second comparator;
a first power supply selection branch coupled between the first power supply node and an internal supply node, and having a control node coupled to an output of the first comparator; and
a second power supply selection branch coupled between the second power supply node and the internal supply node, and having a control node coupled to an output of the second comparator.

9. The circuit of claim 8 wherein a voltage on the first power supply node is coupled to the internal supply node when the voltage on the first power supply node is lower than a voltage on the second power supply node.

10. The circuit of claim 8 wherein a voltage on the second power supply node is coupled to the internal supply node when the voltage on the second power supply node is lower than a voltage on the first power supply node.

11. The circuit of claim 8 wherein the first power supply selection branch comprises a transistor coupled between the first power supply node and the internal supply node, and having a control node coupled to the output of the first comparator.

12. The circuit of claim 11 further comprising a diode coupled between the first power supply node and the transistor.

13. The circuit of claim 8 wherein the second power supply selection branch comprises a transistor coupled between the second power supply node and the internal supply node, and having a control node coupled to the output of the second comparator.

14. The circuit of claim 13 further comprising a diode coupled between the second power supply node and the transistor.

15. The circuit of claim 8 wherein an output of the first comparator is a logic low when a voltage on the first power supply node is less than a voltage on the second power supply node.

16. The circuit of claim 8 wherein an output of the second comparator is a logic low when a voltage on the second power supply node is less than a voltage on the first power supply node.

17. The circuit of claim 8 wherein the first reference generator provides a level shifted version of a voltage on the first power supply node.

18. The circuit of claim 8 wherein the second reference generator provides a level shifted version of a voltage on the second power supply node.

19. The circuit of claim 8 wherein the first reference generator comprises:
a diode-connected transistor coupled between the first power supply node and the first reference output node; and
a current source coupled between the first reference output node and a common node.

20. The circuit of claim 8 wherein the second reference generator comprises:
a diode-connected transistor coupled between the second power supply node and the second reference output node; and
a current source coupled between the second reference output node and a common node.
